(19) United States
(12) Patent Application Publication
(10) Pub. No.: US 2008/0298137 A1
(43) Pub. Date: Dec. 4, 2008

(54) METHOD AND STRUCTURE FOR DOMINO READ BIT LINE AND SET RESET LATCH

(76) Inventors: Yuen Hung Chan, Poughkeepsie, NY (US); Robert Maurice Houle, Williston, VT (US); Rolf Sautter, Bondorf (DE); Pascal Witte, Freiburg (DE)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 12/053,128

(22) Filed: Mar. 21, 2008

(30) Foreign Application Priority Data
Mar. 22, 2007 (DE) 07104632.0

(51) Int. Cl. G11C 7/00; G11C 8/00

(52) U.S. Cl. 365/189.02; 365/230.03; 365/189.05; 365/189.08

(57) ABSTRACT

A domino read bit line structure (20) integral to an SRAM array (1, 2) with thirty-two word lines or less to access SRAM cells divided into two groups (3, 4, 90, 100) is described. The bit line structure (20) includes a dynamic bit decode multiplexer (11, 40) and two NAND circuits (5, 80) used to combine the two groups (3, 4, 90, 100), wherein in order to reduce power consumption the two NANDS (80) drive the dynamic bit decode multiplexer (40) directly, such that true and complement dynamic outputs (rt, rc) drive a set-reset latch (50) to convert the dynamic outputs (rt, rc) to a single static signal (doc), wherein the output of the set-reset latch (50) is already static so that the set-reset latch (50) acts as an effective array output latch (7).

### CROSS REFERENCES TO RELATED APPLICATION

This application is related to one European Application No. 07104632.0 filed Mar. 22, 2007

### FIELD OF THE INVENTION

The invention relates to a domino read bit line structure in conjunction with a small static random access memory (SRAM) array with thirty-two word lines or less plus a set-reset latch for such a bit line structure, which allows to evaluation of the SRAM array during test.

### BACKGROUND OF THE INVENTION

SRAM is a type of semiconductor memory in which the memory retains its contents as long as power remains applied, unlike dynamic random access memory (DRAM) which needs to be periodically refreshed. Each bit in an SRAM is stored in a storage cell comprising four transistors that form two cross-coupled inverters. This storage cell has two stable states which are used to denote ‘0’ and ‘1’. Two additional access transistors serve to control the access to a storage cell during read and write operations. It thus typically takes six transistors, which are typically metal-oxide-semiconductor field-effect transistors (MOSFETs) to store one memory bit. Access to the cell is enabled by a word line which controls the two access transistors and which, in turn, controls whether the cell should be connected to two bit lines. The bit lines are used to transfer data for both read and write operations. While it's not strictly necessary to have two bit lines, both the signal ‘true’ and its inverse ‘complement’ are typically provided since doing so improves noise margins. During read accesses, the bit lines are actively driven high and low by the inverters in the SRAM cell. This improves SRAM speed compared to DRAMs.

SRAM arrays typically are accessed for reading by a so-called domino read structure.

A bit line structure with a standard domino read circuit topology is shown in FIG. 1 in a memory with two small SRAM arrays 1, 2 with thirty-two word lines and two bit lines rglt0, rglc0 each. In the following only the left small SRAM array 1 of FIG. 1 is considered. The thirty-two SRAM cells of the small SRAM array 1 are divided into two groups 3, 4 of sixteen cells each, i.e. in upper and lower halves. The sixteen cells in each group 3, 4 are connected together to one local bit line pair bltu0 and blcu0 for the upper half 3, and bltd0 and blcd0 for the lower half 4. The local bit line pairs bltu0 and blcu0 from the upper 3 and bltd0 and blcd0 from the lower halves 4 are pre-charged high and are connected together by NAND (not and) circuits 5, which drive NFET (Negative Field Effect Transistor) transistors 6. These NFETs 6 drive the two global read bit lines Rglt0, rglc0, which are also pre-charged high. The two global read bit lines rglt0, rglc0 are inverted to reduce noise concerns before connecting to a dynamic bit decode multiplexer 11. In FIG. 1 the dynamic bit decode multiplexer 11 is implemented for a bit decode of two. The bit decode can be varied from two to eight depending on the array requirements.

The true dot and complement outputs doc of the dynamic bit decode multiplexer 11 drive the column redundancy multiplexer 12 which forms the final true and complement read signals t and c. These signals t, c are forwarded to the array output latch 7 which convert the dynamic read signals to a single static output, 12out.

For write operations, there are separate global write bit lines wglt0 and wglc0 which are also pre-charged high. True and complement data from the input latch 8 via the nets dt and dc pass through NFET devices 9 controlled by the AND of the write enable signal wrt and the column select signal bd0 to generate the global write bit lines wglt0 and wglc0 10. The global write bit lines 10 information pass through the local write NFETs 13 to the local bit line when the signal locwrt is active high. It is in this manner that the data from the input latch is transferred to the SRAM cell.

The current state of the art bit line structure with a domino read implementation for small arrays with thirty-two SRAM cells or less utilizes both, local and global bit lines. The global bit lines and the support circuitry are a significant percentage of the small array's area and power consumption. Because the global bit lines are implemented both true and complement lines, one or the other of these global bit lines are always being reset every cycle, which consumes AC power.

### SUMMARY OF THE INVENTION

It is therefore an object of the invention to provide a bit line structure for a small SRAM array with thirty-two word lines or less which requires less devices and which in turn has a reduced power consumption without losing array access performance.

The object of the invention is met by a bit line structure according to claim 1.

Thus in order to reduce power consumption within a bit line circuit for a domino read structure in conjunction with a small SRAM array with thirty-two word lines or less divided into two groups, a bit line structure comprising a dynamic bit decode multiplexer and two NAND circuits is used to combine the two groups of SRAM cells. In order to perform read operations, the NAND circuits drive the dynamic bit decode multiplexer directly. The true and complement dynamic outputs of the dynamic bit decode multiplexer drive a set-reset latch which converts the dynamic outputs to a single ended static signal. In this case, the output of the set-reset latch is already static so that the set-reset latch acts as an effective array output latch. Similar to the prior art approach, the single ended static signal preferably goes through a column redundancy multiplexer, so only the complement half is needed and is buffered through an inverter to produce the final output read signal.

The true and complement local bit lines are read in the same manner as the bit line structure of the prior art. Both bit line structures are pre-charged high with the same capacitive load. This guarantees the same read margin for the SRAM array within the bit line structures according to the invention and according to the state of the art. According to the invention, two NAND circuits are also used to combine the top half with the bottom half, but instead of driving a single NFET which pulls down the global read bit lines, the two NAND circuits drive the dynamic bit decode multiplexer directly. This eliminates the need for the global read bit lines and reduces the access path by two stages. It also reduces the array's fourth metal layer utilization, which eases unit and chip wiring congestion. The dynamic bit decode multiplexer true and complement dynamic outputs drive a set-reset latch which convert the dynamic outputs received as dynamic input signals to a single static signal. As in the prior art approach, the signal still goes through a column redundancy multiplexer. Thereby, according to the invention, now only the complement half is needed. The signal is further buffered through an inverter to produce the final output read signal. The output of the set-reset latch is already static so the final effective array output latch of the prior art approach is not needed, i.e. the set-reset latch acts as the effective array output latch.

According to a preferred embodiment of the invention, during write operations, input latch signals are brought directly to local bit line write circuitry, in order to eliminate the need for global write bit lines. Removing the global write bit lines reduces the total number of NFETs in series required to pull down the local bit line to ground during a write operation from three to two which improves the write performance and write margin of the SRAM cell significantly.

Compared to the prior art bit line structure, the structure claimed herein reduces the number of devices significantly, which saves area and reduces AC and DC power consumption. The bit line structure according to preferred embodiments realized with significantly fewer transistors than prior art implementations, which reduces the layout area by approximately 35%. A lower device count reduces the DC (direct current) leakage power. The preferred embodiments also dissipate 50% less AC (alternating current) power because there are fewer nets switching every cycle (no global read or write bit lines). Also, the output of the set-reset latch is single-ended and switches only when the input data is different than the current latch state so all downstream logic switches only when necessary. The read access time is reduced by approximately 5% by eliminating two stages of logic. Similarly, the write time is improved because there are only two NFETs in series to pull down the local bit line and because the input data signals are shorter in length.

A second object of the invention is met by a set-reset latch converting true and complement dynamic outputs of a dynamic bit decode multiplexer to a single static signal within a bit line structure of a small SRAM array. The set-reset latch element includes two cross-coupled NANDs and another element to shift the differential outputs of the dynamic bit decode multiplexer dynamic output serially through the set-reset latch, in order to evaluate the SRAM array during test operations.

A shift port and gating element are used to propagate the true and complement outputs serially through the set-reset latch. The NAND elements are gated by a shift clock during a test operation. The shift clock avoids the dissipation of active feedback current through the NAND gate This allows a more efficient operation for the set reset latch because the active feedback current is switched off during the time the shift port is open for overwriting the latch content. This circuit topology allows an increased robustness for operations at minimum voltage compared to a solution without gating one of the NANDs. This is because the two NANDs together form a feedback loop that without gating one NAND could only be overwritten when the circuits are operating in a higher voltage range. The shift port preferably uses a shift input and at least one shift clock input which are active during test operations.

According to another preferred embodiment of the set-reset latch, the shift clock gates a single header device during a test operation to disconnect the supply voltage, and gate the feedback loop of the two NAND gates with the shift clock.

The foregoing, together with other objects, features, and advantages of this invention can be better appreciated with reference to the following specification, claims and drawings.

### BRIEF DESCRIPTION OF THE DRAWINGS

FIG. 1 shows a prior art bit line structure within a section of a memory with two small arrays of thirty-two SRAM cells each;

FIG. 2 shows a bit line structure according to a preferred embodiment and;

FIG. 3 shows a set-reset latch for the bit line structure shown in FIG. 2, enabling evaluation of the SRAM array during test operation.

### DETAILED DESCRIPTION

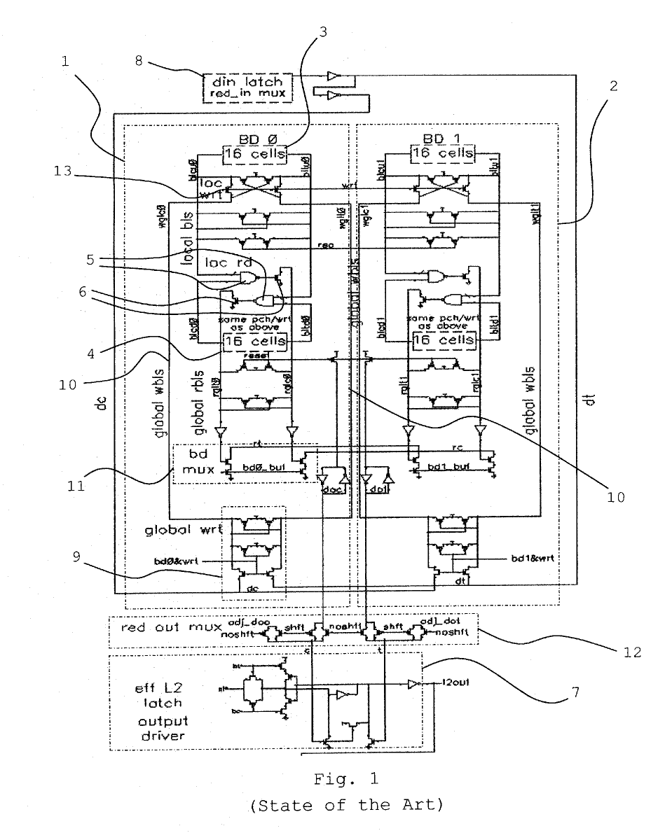

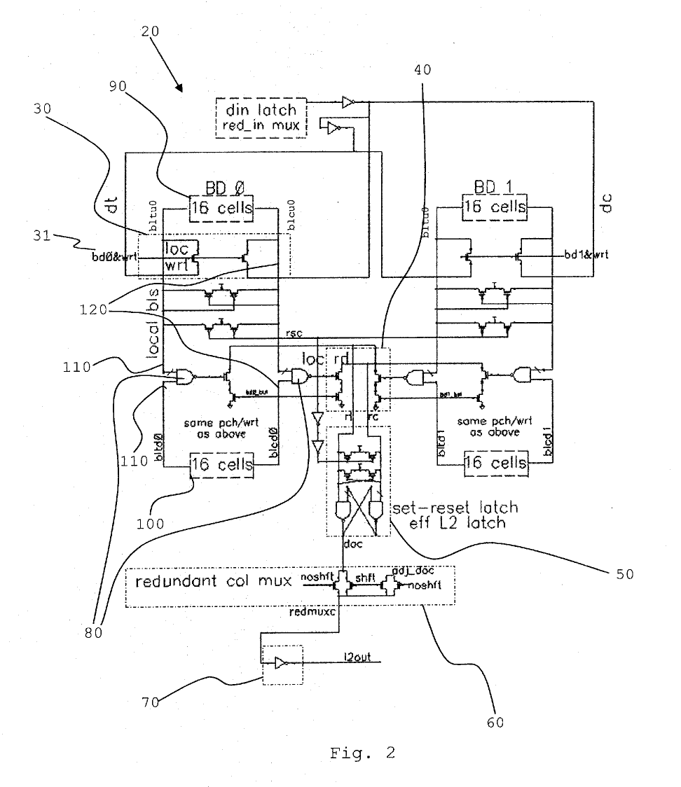

A bit line structure 20 according to a preferred embodiment is shown in FIG. 2, which achieves a significant reduction in device count as compared to the prior art implementation of FIG. 1. This device reduction is achieved by completely removing the read global bit line structures (rglt0 and rglc0 in FIG. 1) and write global bit line structures (wglc0 and wglt0 in FIG. 1). This is made possible by combining the bit decode multiplexer (11 in FIG. 1) directly into the local evaluation circuitry (80 and 40 in FIG. 2) and by incorporating the column select signal (bd0&wrt in FIG. 1) into the local write control signal of FIG. 2.

The true and complement local bit lines bltu0 and blcu0 from the upper 3, and bltd0 and blcd0 from the lower group 4 (FIG. 1) and 110 and 120 respectively (FIG. 2) are read in the same manner in both approaches. They are pre-charged high and realize the same capacitive load. This guarantees the same read margin for the array as in the bit line structure of FIG. 1. Two NAND gates 80 are used to combine the top half 90 with the bottom half 100, but instead of driving a single NFET 6 which pulls down the global read bit lines rglt0, rglc0 (FIG. 1), the two NAND circuits 80 drive the dynamic bit decode multiplexer 40 directly. This eliminates the need for the global read bit lines and reduces the access path by two stages. It also reduces the array's fourth metal layer utilization, which simplifies unit and chip wiring. The true and complement dynamic outputs of the dynamic bit decode multiplexer indicated by the nets rt and rc, drive a set-reset latch 50 which converts its dynamic input signals rt, rc to a single ended static signal, doc. As in the prior art approach, the signal doc still goes through a column redundancy multiplexer 60, but only the complement half is needed, and is buffered through an inverter 70, in order to provide a final output read signal 12out. Since the output of the set-reset latch 50 is already static, the final effective L2 output latch 7 of FIG. 1 is not needed, i.e. the set-reset latch 50 acts as the effective L2 latch 7.

On write operations, the data input latch signals dt and dc are brought directly to the local bit line write circuitry 30, which eliminates the need for the global write bit lines 10 in FIG. 1. The original global write signal bd0&wrt is now used to control the local write logic 31. Removing the global write bit lines reduces the total number of NFETs in series required to pull down the local bit line to ground during the write operation from three to two which improves the write performance and SRAM write margin significantly.

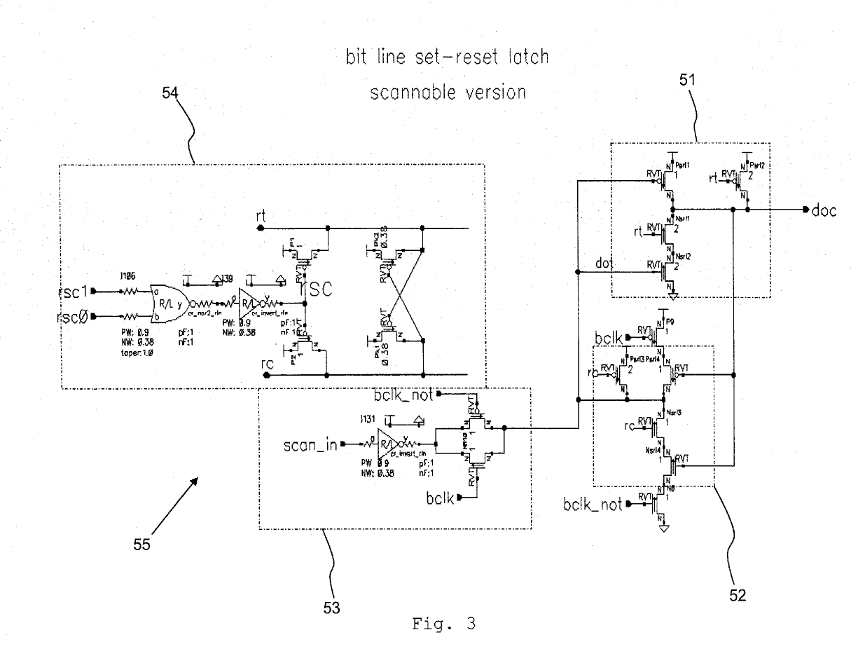

The set-reset latch 55 shown in FIG. 3 converts the true and complement dynamic outputs rt, rc of dynamic bit decode multiplexer 40 (FIG. 2) to a single doc within bit line structure 20. A small SRAM array includes two cross-coupled NAND gates 51, 52 plus transmission gate 53, header P9 and footer NO to shift the true and complement dynamic outputs rt, rc dynamic bit decode multiplexer 40 serially through the set-reset latch 55, in order to evaluate the SRAM arrays during test operations. The set-reset latch 55 includes circuitry 54, which resets the true and complement dynamic outputs rt, rc to active high. The set-reset latch 55 can be used instead of the set-reset latch 50 in FIG. 2.

Shift port 53, header P9 and footer NO gate NAND circuit 52 with shift clocks bclk and bclk_not. The true and complement dynamic outputs rt, rc are shifted serially through set-reset latch 55 during a test. Active feedback current through NAND circuit 52 is avoided by gating NAND circuit 52 via devices P9 and NO from the supply voltage. This enables a better write margin of the set reset latch because the active feedback current of the NAND circuit 52 is switched off while shift port 53 is open for over writing the latch content. This circuit topology allows an increased robustness for operations at minimum voltage compared to a solution without gating one of the NANDs 51, 52. This is because NANDs 51, 52 together form a feedback loop that without gating one NAND 52 could only be overwritten when the circuits are operating in a higher voltage range. The shift port 53 has a shift input scan_in and two shift clock inputs bclk, bclk_not which are active during test operation. Shift clock inputs bclk, bclk_not activate shift input scan_in. During test operation of the SRAM array the normal system clock has to be inactive, which is achieved logic external to the SRAM array.

While the present invention has been described in detail, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

What is claimed is:

1. A domino read bit line structure integral to a multi-bank static random access memory (SRAM) array, comprising:
a dynamic bit decode multiplexer; and
a first latch coupled to the dynamic bit decode multiplexer, the first latch adapted to convert a differential bitline pair output of the dynamic bit decode multiplexer to a single ended signal, wherein the output of the first latch comprises a steady state enabling the first latch to emulate an array output latch.

2. The domino read bit line structure according to claim 1, further comprising a column redundancy multiplexer adapted to buffer the single ended output signal through an inverter to produce a final output read signal.

3. The domino read bit line structure according to claim 1, further comprising a local bit line write circuit element adapted to receive a global write signal to control a local write logic function.

4. The domino read bit line structure according to claim 1, wherein the first latch converting the differential pair output of the dynamic bit decode multiplexer to the single ended signal comprises two cross coupled NAND logic elements configured to shift the differential pair outputs serially through the first latch to evaluate the SRAM array during a test operation.

5. The domino read bit line structure according to claim 4, further comprising a shift port adapted to gate one of the two cross coupled NAND logic elements with a first clock thereby avoiding a feedback current through the gated NAND logic element and enable a subsequent write operation to the two cross coupled NAND logic elements.

6. The domino read bit line structure according to claim 5, wherein the gating of one of the two cross coupled NAND logic elements comprises decoupling the gated NAND logic element from a first power source, such that a feedback loop formed by the two cross coupled NAND logic elements is eliminated.

7. The domino read bit line structure according to claim 1, wherein the first latch comprises a set-reset latch.

8. A method of implementing a domino read bit line structure in a multibank SRAM memory, comprising:
shifting a differential pair signal output of a dynamic bit decode multiplexer of the SRAM array serially through a first latch such that a single ended version of the differential pair signal output is generated; and
gating a power supply to one of a pair of cross coupled logic elements comprising the first latch with a first clock signal, such that a feedback current through the first latch is eliminated.
